(19) United States
(12) Patent Application Publication
(10) Pub. No.: US 2026/0085407 A1
(43) Pub. Date: Mar. 26, 2026

(54) SUBSTRATE PROCESSING METHOD AND SUBSTRATE PROCESSING APPARATUS

(71) Applicant: Tokyo Electron Limited, Tokyo (JP)

(72) Inventors: Yukihiro MUTA, Yamanashi (JP); Masahito SUGIURA, Yamanashi (JP); Takashi MATSUMOTO, Yamanashi (JP)

(21) Appl. No.: 19/403,627

(22) Filed: Nov. 28, 2025

Related U.S. Application Data
(63) Continuation of application No. PCT/JP2024/019581, filed on May 28, 2024.

(30) Foreign Application Priority Data
Jun. 7, 2023 (JP) 2023-094307

(51) Int. Cl. C23C 16/34; C23C 16/458; C23C 16/50; C23C 16/52; H01J 37/32

(52) U.S. Cl. CPC C23C 16/342; C23C 16/4583; C23C 16/50; C23C 16/52; H01J 37/3244; H10P 14/24; H10P 14/3416; H01J 2237/3321

(57) ABSTRACT

Provided are a substrate processing method and a substrate processing apparatus for forming a thin boron nitride film on a substrate. A substrate processing method includes: preparing a substrate including a foundation layer; forming a boron-containing material layer on the substrate by exposing the substrate to a first boron-containing gas; forming a nucleus of a boron nitride-containing material by exposing the substrate on which the boron-containing material layer is formed to a plasma of a first processing gas containing a first nitrogen-containing gas and nitriding the boron-containing material layer; and forming a boron nitride film on the substrate by exposing the substrate on which the nucleus of the boron nitride-containing material is formed to a plasma of a second processing gas containing a second boron-containing gas and a second nitrogen-containing gas different from the first nitrogen-containing gas.

### CROSS-REFERENCE TO RELATED APPLICATIONS

This application is a continuation application of International Application No. PCT/JP2024/019581, filed on May 28, 2024, and designating the U.S., which is based upon and claims priority to Japanese Patent Application No. 2023-094307, filed on Jun. 7, 2023, the entire contents of which are incorporated herein by reference.

### BACKGROUND

### Technical Field The present disclosure relates to a substrate processing method and a substrate processing apparatus.

### Background Art

Japanese Patent Application Laid-Open Publication No. 2002-289618 discloses a film formation method for forming a boron nitride film on a substrate by forming a plasma in a film formation chamber, exciting mainly a nitrogen gas in the film formation chamber, and then allowing the nitrogen gas to react with a boron-based gas, the method characterized by supplying an amorphous phase generation-inhibiting gas in an early period of the film formation to inhibit generation of an amorphous phase on an interface.

### SUMMARY

According to one embodiment, a substrate processing method is provided, including: preparing a substrate including a foundation layer; forming a boron-containing material layer on the substrate by exposing the substrate to a first boron-containing gas; forming a nucleus of a boron nitride-containing material by exposing the substrate on which the boron-containing material layer is formed to a plasma of a first processing gas containing a first nitrogen-containing gas and nitriding the boron-containing material layer; and forming a boron nitride film on the substrate by exposing the substrate on which the nucleus of the boron nitride-containing material is formed to a plasma of a second processing gas containing a second boron-containing gas and a second nitrogen-containing gas different from the first nitrogen-containing gas.

### BRIEF DESCRIPTION OF THE DRAWINGS

FIG. 1 is a schematic cross-sectional view showing an example of a substrate processing apparatus according to the present embodiment;

FIG. 2 is a flowchart showing an example of an h-BN film formation method according to the present embodiment;

FIG. 3A is an example of a schematic cross-sectional view of a substrate W in each step according to the present embodiment;

FIG. 3B is an example of a schematic cross-sectional view of a substrate W in each step according to the present embodiment;

FIG. 3C is an example of a schematic cross-sectional view of a substrate W in each step according to the present embodiment;

FIG. 3D is an example of a schematic cross-sectional view of a substrate W in each step according to the present embodiment;

FIG. 3E is an example of a schematic cross-sectional view of a substrate W in each step according to the present embodiment;

FIG. 4 is an example of a graph showing the relationship between nitrogen-containing gases and a nitridation reaction;

FIG. 5 is a flowchart showing an example of an h-BN film formation method according to a Reference Example;

FIG. 6A is an example of a schematic cross-sectional view of a substrate W in each step according to the Reference Example;

FIG. 6B is an example of a schematic cross-sectional view of a substrate W in each step according to the Reference Example;

FIG. 6C is an example of a schematic cross-sectional view of a substrate W in each step according to the Reference Example;

FIG. 7 is an example of a graph showing the relationship between nitrogen-containing gases and nitridation reaction;

FIG. 8 is a cross-sectional view showing a boron nitride film formed by the h-BN film formation method according to the present embodiment; and

FIG. 9 is a cross-sectional view showing a boron nitride film formed by the h-BN film formation method according to the Reference Example.

### DETAILED DESCRIPTION OF THE INVENTION

Hereinafter, an embodiment for carrying out the present disclosure will be described with reference to the drawings. In the drawings, the same components are denoted by the same reference numerals and redundant descriptions thereof may be omitted.

### Substrate Processing Apparatus

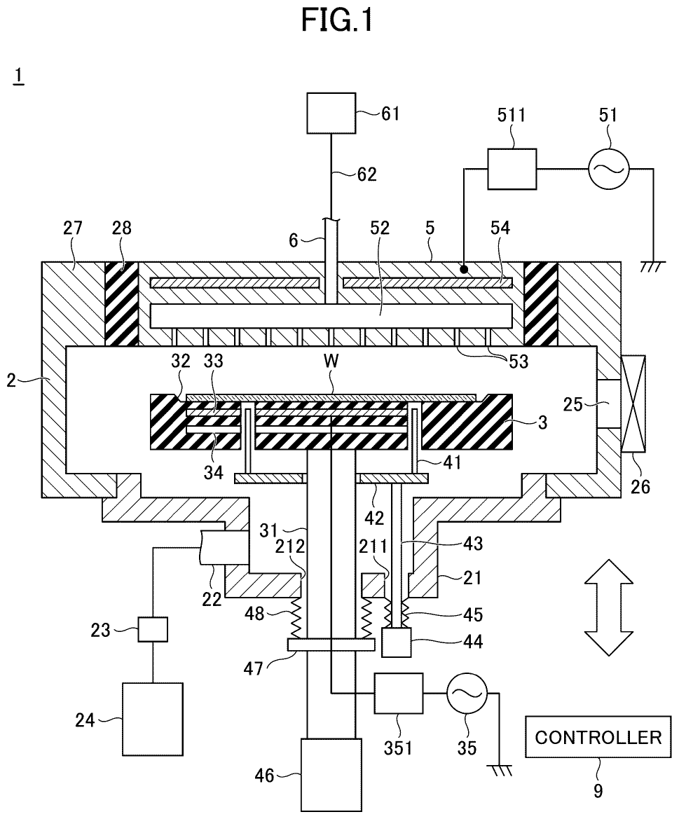

An example of a substrate processing apparatus 1 according to the present embodiment will be described with reference to FIG. 1. FIG. 1 is a schematic cross-sectional view showing an example of a substrate processing apparatus 1 according to the present embodiment. The substrate processing apparatus 1 is a film formation apparatus for forming a Hexagonal Boron Nitride (hereinafter also referred to as “h-BN”) film on a substrate W, such as a wafer and the like, by a Plasma-Enhanced Chemical Vapor Deposition (PE-CVD) method in a processing vessel 2 at a reduced pressure.

The substrate processing apparatus 1 includes a substantially cylindrical airtight processing vessel 2. A gas exhaust chamber 21 is provided in the center of the bottom wall of the processing vessel 2.

The gas exhaust chamber 21 has, for example, a substantially cylindrical shape projecting downward. A gas exhaust flow path 22 is connected to the gas exhaust chamber 21 on, for example, a side surface of the gas exhaust chamber 21. A gas exhaust part 24 is connected to the gas exhaust flow path 22 via a pressure regulator 23. The pressure regulator 23 includes, for example, a pressure regulating valve, such as a butterfly valve and the like. The gas exhaust flow path 22 is configured to allow the interior of the processing vessel 2 to be depressurized by the gas exhaust part 24. A conveying port 25 is provided on a side surface of the processing vessel 2. The conveying port 25 is openable and closable by a gate valve 26. The substrate W is loaded into or unloaded from the processing vessel 2, from or into a conveying chamber (not shown), via the conveying port 25.

A mounting table 3 for holding the substrate W substantially horizontally is provided in the processing vessel 2. The mounting table 3 has a substantially circular shape in a plan view and is supported by a support member 31. A substantially circular recess 32 for mounting a substrate W having a diameter of, for example, 300 mm is formed in the surface of the mounting table 3. The recess 32 has an inner diameter slightly greater (for example, by approximately 1 mm to 4 mm) than the diameter of the substrate W. The depth of the recess 32 is, for example, substantially equal to the thickness of the substrate W. The mounting table 3 is composed of a ceramic material, such as aluminum nitride (AlN) and the like. The mounting table 3 may be composed of a metal material, such as nickel (Ni) and the like. Instead of the recess 32, a guide ring for guiding the substrate W may be provided at the peripheral edge of the surface of the mounting table 3.

A lower electrode 33 is embedded in the mounting table 3. A temperature regulating mechanism 34 is embedded under the lower electrode 33. The temperature regulating mechanism 34 regulates the substrate W mounted on the mounting table 3 to a set temperature based on a control signal from a controller 9. When the entire mounting table 3 is composed of a metal, the entire mounting table 3 functions as a lower electrode. Therefore, the lower electrode 33 does not need to be embedded in the mounting table 3.

An RF power source 35 is connected to the lower electrode 33 via a matcher 351. The RF power source 35 applies a low-frequency power (LF) having a frequency lower than the frequency of an RF power source 51 described later to the lower electrode 33. A high-frequency power generated by the RF power source 35 is used as a bias high-frequency power for drawing ions into the substrate W. The frequency of the RF power source 35 is, for example, 13.56 MHz.

The mounting table 3 is provided with a plurality of (for example, three) lifting pins 41 for raising or lowering the substrate W mounted on the mounting table 3 while holding the substrate W. The material of the lifting pins 41 may be, for example, ceramics, such as alumina (Al₂O3) and the like, or quartz and the like. The lower ends of the lifting pins 41 are attached to a support plate 42. The support plate 42 is connected to a lifting mechanism 44 provided outside the processing vessel 2 via a lifting shaft 43.

The lifting mechanism 44 is provided at, for example, a lower part of the gas exhaust chamber 21. A bellows 45 is provided between an opening 211 for the lifting shaft 43, formed in the lower surface of the gas exhaust chamber 21, and the lifting mechanism 44. The shape of the support plate 42 may be a shape that can be raised or lowered without interfering with the support member 31 of the mounting table 3. The lifting pins 41 are configured to be raised and lowered by the lifting mechanism 44 between an upper side of the surface of the mounting table 3 and a lower side of the surface of the mounting table 3. In other words, the lifting pins 41 are configured to be projectable from the upper surface of the mounting table 3.

The lower end of the support member 31 penetrates an opening 212 of the gas exhaust chamber 21 and is supported by a lifting mechanism 46 via a lifting plate 47 disposed under the processing vessel 2. A bellows 48 is provided between the bottom of the gas exhaust chamber 21 and the lifting plate 47, and the airtightness in the processing vessel 2 is maintained even in response to the vertical movement of the lifting plate 47.

By the lifting mechanism 46 raising or lowering the lifting plate 47, the mounting table 3 can be raised or lowered. Thus, the gap between the mounting table 3 and a gas supply 5 can be adjusted.

The gas supply 5 is provided on a top wall 27 of the processing vessel 2 via an insulating member 28. The gas supply 5 forms an upper electrode and faces the lower electrode 33. The RF power source 51 is connected to the gas supply 5 via a matcher 511. The RF power source 51 applies a high-frequency power having a frequency higher than the frequency of the RF power source 35 to the upper electrode (gas supply 5). The high-frequency power generated by the RF power source 51 is used as a high-frequency power for plasma formation necessary for film formation on the substrate W. The frequency of the RF power source 51 is, for example, in a Very High Frequency (VHF) band of 100 MHz to 900 MHz. By supplying an RF power from the RF power source 51 to the upper electrode (gas supply 5), an RF electric field is generated between the upper electrode (gas supply 5) and the lower electrode 33. The RF power source 51, the upper electrode (gas supply 5), and the lower electrode 33 constitute a plasma formation part for forming a plasma. The gas supply 5 includes a hollow gas diffusion chamber 52. In the lower surface of the gas diffusion chamber 52, multiple holes 53 for dispersedly supplying a processing gas into the processing vessel 2 are arranged, for example, uniformly. A heating mechanism 54 is buried, for example, above the gas diffusion chamber 52 of the gas supply 5. The heating mechanism 54 is heated to a set temperature by being supplied with power from a power source (not shown) based on a control signal from the controller 9.

The gas diffusion chamber 52 is provided with a gas supply flow path 6. The gas supply flow path 6 communicates with the gas diffusion chamber 52. A gas source 61 is connected to the upstream side of the gas supply flow path 6 via a gas line 62. The gas source 61 includes, for example, supply sources of various processing gases, a mass flow controller, and a valve (none of which is shown). Examples of the various processing gases include a boron-containing gas and a nitrogen-containing gas used for forming an h-BN film. Examples of the various processing gases also include an inert gas (for example, Ar gas) for forming a plasma. The various processing gases are introduced into the gas diffusion chamber 52 from the gas source 61 via the gas line 62.

The substrate processing apparatus 1 includes the controller 9. The controller 9 is, for example, a computer, and includes a Central Processing Unit (CPU), a Random Access Memory (RAM), a Read Only Memory (ROM), an auxiliary storage device, and the like. The CPU operates based on a program stored in the ROM or the auxiliary storage device, and controls the operation of the substrate processing apparatus 1. The controller 9 may be provided inside or outside the substrate processing apparatus 1. When the controller 9 is provided outside the substrate processing apparatus 1, the controller 9 can control the substrate processing apparatus 1 by a wired, wireless, or other communication method.

h-BN film formation method

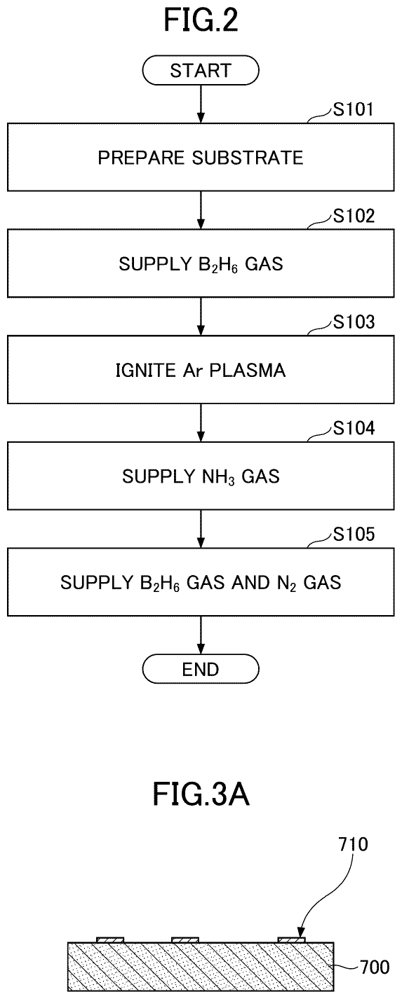

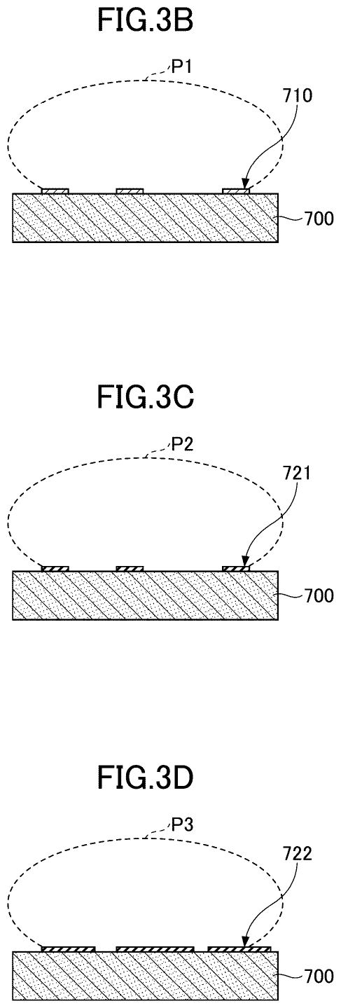

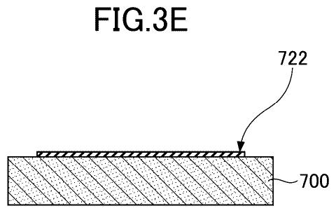

Next, an example of an h-BN film formation method (substrate processing method) according to the present embodiment will be described with reference to FIGS. 2 and 3A to 3E. FIG. 2 is a flowchart showing an example of the h-BN film formation method according to the present embodiment. FIGS. 3A to 3E are schematic cross-sectional views of a substrate W in each step according to the present embodiment.

In step S101, a substrate W is prepared. The substrate W has a foundation layer 700 (see FIG. 3A described later). The foundation layer 700 is, for example, any one of SiO₂, HfO₂, HfSiO₄, HfSiON, ZrO₂, amorphous silicon, sapphire, or the like. Here, the controller 9 controls a conveying device (not shown) to place the substrate W on the mounting table 3 of the substrate processing apparatus 1. When the conveying device retreats from the conveying port 25, the controller 9 closes the gate valve 26.

In step S102, a first boron-containing gas (for example, B₂H₆) is supplied into the processing vessel 2. Here, the controller 9 controls the valve or the like of the gas source 61 to supply the first boron-containing gas into the processing vessel 2. Thus, the substrate W in the processing vessel 2 is exposed to the first boron-containing gas, and a boron-containing material layer (also referred to as a boron-containing film) 710 is formed on the surface of the foundation layer 700 of the substrate W. When a predetermined processing time has elapsed, the controller 9 controls the valve or the like of the gas source 61 to stop the supply of the first boron-containing gas into the processing vessel 2.

Here, the first boron-containing gas is at least one of B₂H₆ (diborane), BCl₃ (boron trichloride), B₃N₃H₆ (borazine), B(CH₃)₃ (trimethyl borane), or the like. In the following description, a case where the first boron-containing gas is B₂H₆ will be described as an example.

An example of the recipe in step S102 is shown.

Pressure in the processing vessel: 10 mTorr to 200 mTorr

Mounting table temperature: 600° C. to 900° C. FIG. 3A is an example of a schematic cross-sectional view of the substrate W after the step S102. By supplying the first boron-containing gas to the substrate W, the boron-containing material layer 710 is formed by CVD film formation. Alternatively, by supplying the first boron-containing gas to the substrate W, the first boron-containing gas adsorbs to the surface of the foundation layer 700 of the substrate W to form the boron-containing material layer 710. Here, the boron-containing material layer 710 may be discontinuous films formed on at least part of the film-formation surface of the substrate W (the foundation layer 700) (in the example of FIGS. 3A to 3E, the film-formation surface is the upper surface of the foundation layer 700), or may be a continuous film.

In step S103, a plasma of Ar gas is ignited in the processing vessel 2. Here, the controller 9 controls the valve or the like of the gas source 61 to supply an inert gas for forming a plasma (also referred to as a plasma formation gas) into the processing vessel 2. The inert gas is, for example, at least one of Ar, He, or the like. In the following description, a case where the inert gas is Ar gas will be described as an example. Further, the controller 9 controls the RF power source 51 to supply a high-frequency power for plasma formation to the upper electrode. Thus, a plasma of Ar gas is ignited between the upper electrode (gas supply 5) and the lower electrode 33.

FIG. 3B is an example of a schematic cross-sectional view of the substrate W in step S103. A plasma P1 of Ar gas is formed in the processing vessel 2. The substrate W is exposed to the plasma P1 of Ar gas.

In step S104, a first nitrogen-containing gas (for example, NH₃) is supplied into the processing vessel 2. Here, in a state in which the plasma P1 of Ar gas is formed, the controller 9 controls the valve or the like of the gas source 61 to supply the first nitrogen-containing gas into the processing vessel 2. Thus, the substrate W in the processing vessel 2 is exposed to a plasma of a first processing gas containing the first nitrogen-containing gas and Ar gas. Thus, the boron-containing material layer 710 is nitrided to form nuclei 721 of a boron nitride-containing material. When a predetermined processing time has elapsed, the controller 9 controls the valve or the like of the gas source 61 to stop the supply of the first nitrogen-containing gas into the processing vessel 2.

Here, the first nitrogen-containing gas is, for example, at least one gas selected from NH₃ (ammonia), a mixed gas of N₂ and H₂, monomethyl hydrazine, and the like. In the following description, a case where the first nitrogen-containing gas is NH₃ will be described as an example.

An example of the recipe in step S104 is shown.

Pressure in the processing vessel: 10 mTorr to 200 mTorr

Mounting table temperature: 600° C. to 900° C.

The pressure in step S104 is equal to or higher than the pressure in step S105, which will be described later. At an equal or higher pressure, the nitriding speed is restricted, and unnecessary growth is inhibited, which facilitates obtaining discontinuous films.

FIG. 3C is an example of a schematic cross-sectional view of the substrate W in step S104. A plasma P2 of the first processing gas containing the first nitrogen-containing gas (NH₃) and Ar gas is formed in the processing vessel 2. The boron-containing material layer 710 (see FIG. 3B) is nitrided by the plasma P2 of the first processing gas, and nuclei of a boron nitride-containing material (also referred to as first boron nitride films) 721 are formed. Here, the nuclei 721 of the boron nitride-containing material are discontinuous films formed on at least part of the film-formation surface of the substrate W (the foundation layer 700) (in the example of FIGS. 3A to 3E, the film-formation surface is the upper surface of the foundation layer 700).

In step S105, a second boron-containing gas (for example, B₂H₆) and a second nitrogen-containing gas (for example, N₂) are supplied into the processing vessel 2. Here, in a state in which the plasma P1 of Ar gas is formed, the controller 9 controls the valve or the like of the gas source 61 to supply the second boron-containing gas and the second nitrogen-containing gas into the processing vessel 2. Thus, the substrate W in the processing vessel 2 is exposed to a plasma of a second processing gas containing the second boron-containing gas, the second nitrogen-containing gas, and Ar gas. Thus, boron nitride films (also referred to as second boron nitride films) 722 are formed, starting from the nuclei 721 of the boron nitride-containing material. When a predetermined processing time has elapsed, the controller 9 controls the valve or the like of the gas source 61 to stop the supply of the second boron-containing gas and the second nitrogen-containing gas into the processing vessel 2. The controller 9 also controls the RF power source 51 to stop the supply of the high-frequency power to the upper electrode. Further, the controller 9 controls the valve or the like of the gas source 61 to stop the supply of Ar gas into the processing vessel 2.

Here, the second boron-containing gas is, for example, at least one gas selected from B₂H₆, BCl₃, B₃N₃H₆, B(CH₃)₃, and the like. The second boron-containing gas may be the same gas as the first boron-containing gas, or may be a different gas. In the following description, a case where the second boron-containing gas is B₂H₆ will be described as an example.

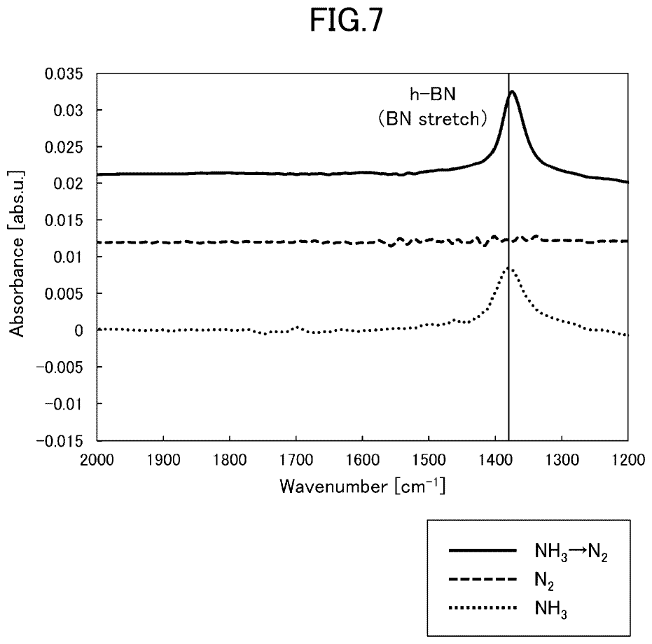

The second nitrogen-containing gas is a gas different from the first nitrogen-containing gas. Further, the second nitrogen-containing gas is a nitrogen-containing gas that is poorer than the first nitrogen-containing gas in terms of the reactivity for nitriding boron-containing materials (the first boron-containing gas, the second boron-containing gas, and the boron-containing material layer 710). Further, as shown in FIG. 7 described later, when the substrate W on which no nuclei 721 of the boron nitride-containing material are formed is exposed to the plasma of the second processing gas containing the second boron-containing gas and the second nitrogen-containing gas, boron nitride film formation is inhibited. Specifically, since there are no reaction terminals on the surface of the nuclei 721 of the boron nitride-containing material, boron nitride film formation by nitridation of boron does not occur, and no boron nitride film grows (forms) in the lamination direction. Since the nuclei 721 of the boron nitride-containing material have reaction terminals only in the plane direction, boron nitride film grows (forms) in the plane direction. The second nitrogen-containing gas is, for example, at least any one of N₂, a mixed gas of N₂ and H₂, or the like. When the second nitrogen-containing gas is a mixed gas of N₂ and H₂, the second nitrogen-containing gas is supplied at a different nitrogen-to-hydrogen ratio from that of the first nitrogen-containing gas, for example, by bringing the second nitrogen-containing gas close to a condition of being only N₂, by extremely reducing the partial pressure of N_{2,} or by other methods. In the following description, a case where the second nitrogen-containing gas is N₂ will be described as an example.

An example of the recipe in step S105 is shown.

Pressure in the processing vessel: 10 mTorr to 200 mTorr

Mounting table temperature: 600° C. to 900° C. FIG. 3D is an example of a schematic cross-sectional view of the substrate W in step S105. A plasma P3 of the second processing gas containing the second boron-containing gas (B₂H₆), the second nitrogen-containing gas (N₂), and Ar gas is formed in the processing vessel 2. By the plasma P3 of the second processing gas, the boron nitride films 722 are grown in the plane direction of the substrate W, starting from the nuclei 721 of the boron nitride-containing material (see FIG. 3C). Meanwhile, the growth of the boron nitride films 722 in the lamination direction of the substrate W is inhibited as compared with the Reference Example described later.

FIG. 3E is an example of a schematic cross-sectional view of the substrate W after step S105. By the growth of the boron nitride films 722 in the plane direction of the substrate W, a boron nitride film 722 is formed on the foundation layer 700 of the substrate W. Further, the growth of the boron nitride films 722 in the lamination direction is inhibited, to form a thin boron nitride film 722 on the substrate W.

The h-BN film formation method according to the present embodiment is performed by the substrate processing apparatus 1 shown in FIG. 1. In other words, the step of forming the boron-containing material layer 710 (S102), the step of forming the nuclei 721 of the boron nitride-containing material (S104), and the step of forming the boron nitride film 722 (S105) are performed in one processing vessel 2. However, the present invention is not limited to this. For example, the step of forming the boron-containing material layer 710 (S102), the step of forming the nuclei 721 of the boron nitride-containing material (S104), and the step of forming the boron nitride film 722 (S105) may be performed in different processing vessels. For example, a substrate processing system may be a multi-chamber substrate processing system including: a first substrate processing apparatus for performing the step of forming the boron-containing material layer 710 (S102); a second substrate processing apparatus for performing the step of forming the nuclei 721 of the boron nitride-containing material (S104); a third substrate processing apparatus for performing the step of forming the boron nitride film 722 (S105); a vacuum conveying apparatus connected to the first to third substrate processing apparatuses; a substrate conveying apparatus provided in the vacuum conveying apparatus; and the like.

For example, a substrate processing system may be a multi-chamber substrate processing system including: a first substrate processing apparatus for performing the step of forming the boron-containing material layer 710 (S102) and the step of forming the nuclei 721 of the boron nitride-containing material (S104); a second substrate processing apparatus for performing the step of forming the boron-nitride film 722 (S105); a vacuum conveying apparatus connected to the first and second substrate processing apparatuses; a substrate conveying apparatus provided in the vacuum conveying apparatus; and the like.

For example, a substrate processing system may be a multi-chamber substrate processing system including: a first substrate processing apparatus for performing the step of forming the boron-containing material layer 710 (S102); a second substrate processing apparatus for performing the step of forming the nuclei 721 of the boron nitride-containing material (S104) and the step of forming the boron-nitride film 722 (S105); a vacuum conveying apparatus connected to the first and second substrate processing apparatuses; a substrate conveying apparatus provided in the vacuum conveying apparatus; and the like.

The example shown in FIG. 2 has been described as an example in which the step of forming the boron-containing material layer 710 (S102), the step of forming the nuclei 721 of the boron nitride-containing material, and the step of forming the boron-nitride film 722 (S105) are each performed one time. However, the present invention is not limited to this. Regarding the process from step S102 to step S105 as one cycle, this cycle may be repeated a plurality of times. Thus, the film thickness of the boron-nitride film formed on the substrate W can be controlled based on the number of times the cycle is repeated. As will be described later, the h-BN film formation method according to the present embodiment can reduce the film thickness of the boron nitride film per one cycle. Therefore, the controllability of the film thickness of the boron nitride film is improved.

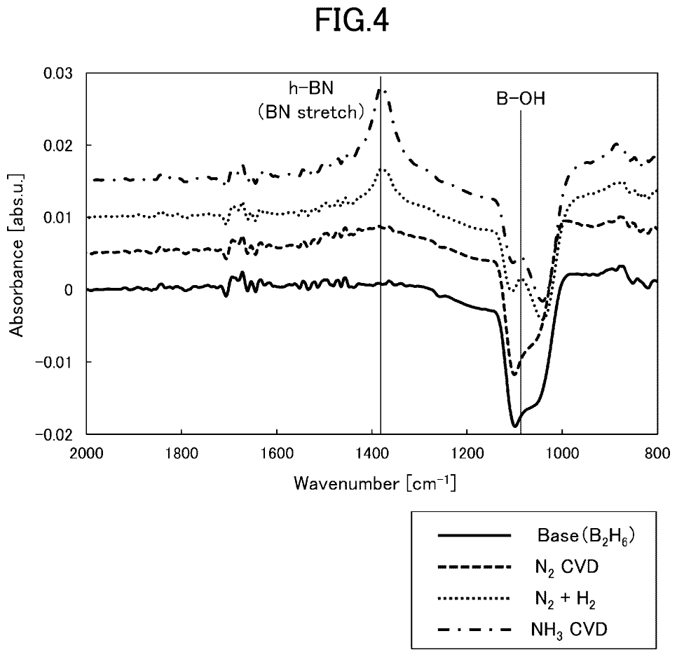

Here, the process of forming the nuclei 721 of the boron nitride-containing material by nitriding the boron-containing material layer 710 in steps S101 to S105 will be further described with reference to FIG. 4. FIG. 4 is an example of a graph showing the relationship between nitrogen-containing gases and the nitridation reaction. Here, each film formed on the substrate W was analyzed by Fourier transform infrared spectroscopy (FT-IR). The horizontal axis represents wavelength (Wavenumber). The vertical axis represents absorbance (Absorbance). In FIG. 4, the position of the wavelength corresponding to h-BN and the position of the wavelength corresponding to B-OH are indicated by thin solid lines.

“Base (B₂H₆)” indicated by a solid line represents the boron-containing material layer 710 formed on the substrate W having the foundation layer 700 composed of SiO₂, using B₂H₆ as the first boron-containing gas (see FIG. 2, step S102).

“N₂ CVD” indicated by a broken line represents a nitridation treatment performed, using a plasma of a processing gas containing N₂ and Ar, on the substrate W on which the boron-containing material layer 710 was formed using B₂H₆. “N₂+H₂” indicated by a dotted line represents a nitridation treatment performed, using a plasma of a processing gas containing N₂, H₂, and Ar (see FIG. 2, steps S103 and S104), on the substrate W on which the boron-containing material layer 710 was formed using B₂H₆. That is, this corresponds to the case where a mixed gas of N₂ and H₂ is used as the first nitrogen-containing gas in the h-BN film formation method according to the present embodiment.

“NH₃ CVD” indicated by a dashed line represents a nitridation treatment performed, using a plasma of a processing gas containing NH₃ and Ar (see FIG. 2, steps S103 and S104), on the substrate W on which the boron-containing material layer 710 was formed using B₂H₆. That is, this corresponds to the case where NH₃ gas is used as the first nitrogen-containing gas in the h-BN film formation method according to the present embodiment.

As shown in FIG. 4, in “N₂+H₂” indicated by the dotted line and “NH₃ CVD” indicated by the dashed line, absorbance peaks appeared at the wavelength position corresponding to h-BN. That is, the nuclei 721 of the boron nitride-containing material were formed on the substrate W by the process from steps S101 to S105. Further, among the cases of forming the boron-containing material layer 710 on the substrate W by B₂H₆ and then nitriding it by a plasma of a processing gas containing a nitrogen-containing gas, “N₂+H₂” indicated by the dotted line and “NH₃ CVD” indicated by the dashed line show that the reaction speed at which h-BN was formed was higher, compared to “N₂ CVD” indicated by the broken line.

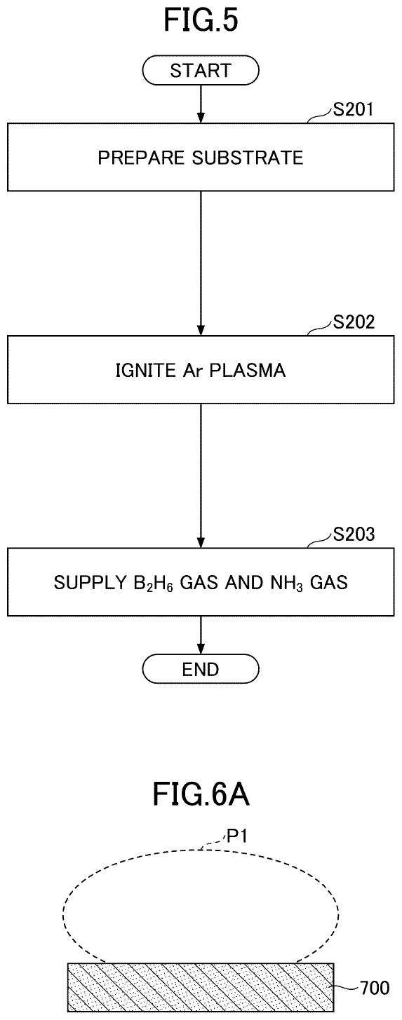

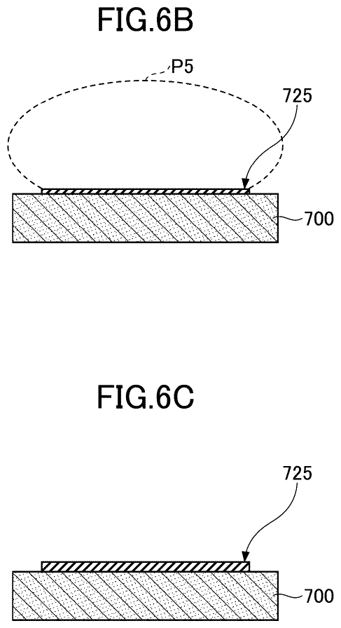

Next, an example of an h-BN film formation method (substrate processing method) according to the Reference Example will be described with reference to FIGS. 5 and 6A to 6C. FIG. 5 is a flowchart showing an example of an h-BN film formation method according to the Reference Example. FIGS. 6A to 6C are examples of schematic cross-sectional views of the substrate W in each step according to the Reference Example.

In step S201, a substrate W is prepared. The substrate W has a foundation layer 700 (see FIG. 6A described later). Here, the controller 9 controls the conveying device (not shown) to place the substrate W on the mounting table 3 of the substrate processing apparatus 1. When the conveying device retreats from the conveying port 25, the controller 9 closes the gate valve 26.

In step S202, a plasma of Ar gas is ignited in the processing vessel 2. Here, the controller 9 controls the valve or the like of the gas source 61 to supply Ar gas for forming a plasma into the processing vessel 2. The controller 9 also controls the RF power source 51 to supply a high-frequency power for plasma formation to the upper electrode. Thus, a plasma of Ar gas is ignited between the upper electrode (gas supply 5) and the lower electrode 33.

FIG. 6A is an example of a schematic cross-sectional view of the substrate W in the step S202. A plasma P1 of Ar gas is formed in the processing vessel 2. The substrate W is exposed to the plasma P1 of Ar gas.

In step S203, B₂H₆ gas (boron-containing gas) and NH₃ gas (nitrogen-containing gas) are supplied into the processing vessel 2. Here, from a state in which the plasma P1 of Ar gas is formed, the controller 9 controls the valve or the like of the gas source 61 to supply B₂H₆ gas and NH₃ gas into the processing vessel 2. Thus, the substrate W in the processing vessel 2 is exposed to a plasma P5 of a processing gas according to the Reference Example, containing B₂H₆ gas, NH₃ gas, and Ar gas. Thus, a boron nitride film 725 is formed on the substrate W. When a predetermined processing time has elapsed, the controller 9 controls the valve or the like of the gas source 61 to stop the supply of B₂H₆ gas and NH₃ gas into the processing vessel 2. The controller 9 also controls the RF power source 51 to stop the supply of the high-frequency power to the upper electrode. The controller 9 also controls the valve or the like of the gas source 61 to stop the supply of Ar gas into the processing vessel 2.

FIG. 6b Is an Example of a Schematic Cross-sectional View of the substrate W in step S203. The plasma P5 of the processing gas according to the Reference Example, containing B₂H₆ gas, NH₃ gas, and Ar gas is formed in the processing vessel 2. Thus, the boron nitride film 725 is formed on the substrate W. Here, as will be described later, the boron nitride film 725 grows in the lamination direction and the plane direction.

FIG. 6C is an example of a schematic cross-sectional view of the substrate W after the step S203. By the growth of the boron nitride film 725 in the lamination direction and the plane direction of the substrate W, the boron nitride film 725 is formed on the foundation layer 700 of the substrate W.

Next, the h-BN film formation method according to the present embodiment (see FIG. 2, and 3A to 3E) will be further described in comparison with the h-BN film formation method according to the Reference Example (see FIGS. 5 and 6A to 6C). FIG. 7 is an example of a graph showing the relationship between nitrogen-containing gases and the nitridation reaction. Here, each film formed on the substrate W was analyzed by Fourier transform infrared spectroscopy (FT-IR). The horizontal axis represents wavelength (Wavenumber). The vertical axis represents absorbance (Absorbance).

“NH₃→N₂” indicated by a solid line corresponds to the h-BN film formation method according to the present embodiment (see FIGS. 2 and 3A to 3E), in which the substrate W on which a boron-containing material layer 710 was formed using B₂H₆ was subjected to nitridation treatment using a plasma of the first processing gas containing NH₃ and Ar (see FIG. 2, steps S103 and S104), and then boron nitride films 722 were formed on the substrate W using a plasma of the second processing gas containing B₂H₆, N₂, and Ar (see FIG. 2, step S105).

“NH₃” indicated by a broken line corresponds to the h-BN film formation method according to the Reference Example (see FIGS. 5 and 6A to 6C), in which a boron nitride film 725 was formed on the substrate W using a plasma of a processing gas containing B₂H₆, NH₃, and Ar (see FIG. 5, steps S202 and S203).

“N₂” indicated by a broken line represents a case where NH₃ was changed to N₂ as the nitrogen-containing gas in the h-BN film formation method according to the Reference Example (see FIGS. 5 and 6A to 6C). That is, “N₂” indicated by the broken line corresponds to an h-BN film formation method according to another the Reference Example, in which a boron nitride film was formed on the substrate W using a plasma of a processing gas containing B₂H₆, N₂, and Ar.

As shown in FIG. 7, in the h-BN film formation method according to the present embodiment, a peak appeared at the wavelength position corresponding to h-BN (see FIG. 4, around 1,400 cm⁻¹). That is, it was indicated that an h-BN film was formed.

Further, in the h-BN film formation method according to the Reference Example using NH₃ as the nitrogen-containing gas, a peak appeared at the wavelength position corresponding to h-BN (see FIG. 4, around 1,400 cm⁻¹). That is, it was indicated that an h-BN film was formed.

On the other hand, in an h-BN film formation method according to the another Reference Example using N₂ as the nitrogen-containing gas, no peak appeared at the wavelength position corresponding to h-BN (see FIG. 4, around 1,400 cm⁻¹). That is, it was indicated that no h-BN film was deposited.

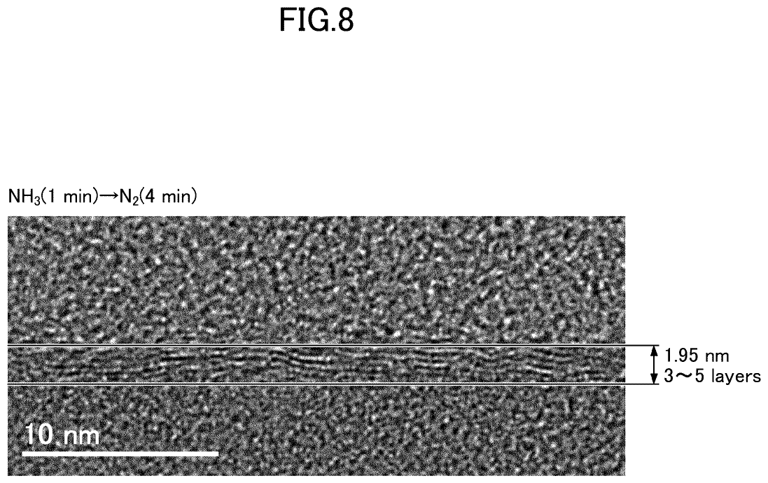

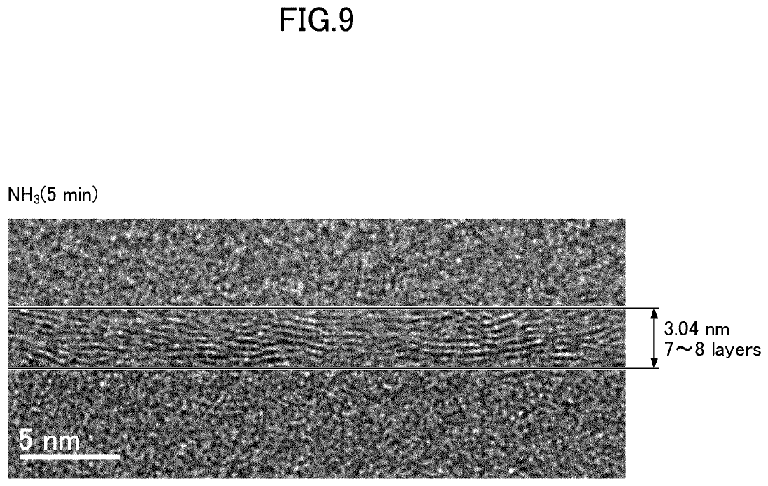

FIG. 8 is a cross-sectional view showing the boron nitride film 722 formed by the h-BN film formation method according to the present embodiment (see FIGS. 2 and 3A to 3E). FIG. 9 is a cross-sectional view showing the boron nitride film 725 formed by the h-BN film formation method according to the Reference Example (see FIGS. 5 and 6A to 6C).

In the example shown in FIG. 8, the boron nitride film 722 was

formed by performing the process of step S104 for 1 min and the process of step S105 for 4 min. Here, the boron nitride film 722 including three to five layers and having a film thickness of 1.95 nm was formed.

Meanwhile, in the example shown in FIG. 9, the boron nitride film 725 was formed by performing the process of step S203 for 5 min. Here, the boron nitride film 725 including seven to eight layers and having a film thickness of 3.04 nm was formed.

As shown in a comparison between FIGS. 8 and 9, according to the h-BN film formation method according to the present embodiment (see FIG. 2, and 3A to 3E), a thin boron nitride film 722 can be formed on the substrate W.

That is, by separately performing the step of supplying the first boron-containing gas (S102) and the step of exposing the substrate to the plasma of the first processing gas containing the first nitrogen-containing gas, it is possible to restrict the lamination direction thickness of the nuclei 721 of the boron nitride-containing material to be formed on the substrate W.

In the step of exposing the substrate to the plasma of the second processing gas containing the second boron-containing gas and the second nitrogen-containing gas (S105), as shown in FIGS. 4 and 7, it is possible to use a combination of gases by which a boron nitride film does not grow favorably on the substrate W as is. Thus, the boron nitride film 722 can be grown from the nuclei 721 of the boron nitride-containing material in the plane direction of the substrate W. On the other hand, the growth of the boron nitride film 722 in the lamination direction of the substrate W can be inhibited. Thus, a thin boron nitride film 722 can be formed on the substrate W.

Although the substrate processing method for forming a boron nitride film has been described above, the present disclosure is not limited to the above-described embodiment and other particulars, and various modifications and improvements are applicable within the scope of the spirit of the present disclosure described in the claims.

According to one aspect, the present disclosure can provide a substrate processing method and a substrate processing apparatus for forming a thin boron nitride film on a substrate.

What is claimed is:

1. A substrate processing method, comprising:
preparing a substrate including a foundation layer;
forming a boron-containing material layer on the substrate by exposing the substrate to a first boron-containing gas;
forming a nucleus of a boron nitride-containing material by exposing the substrate on which the boron-containing material layer is formed to a plasma of a first processing gas containing a first nitrogen-containing gas and nitriding the boron-containing material layer; and
forming a boron nitride film on the substrate by exposing the substrate on which the nucleus of the boron nitride-containing material is formed to a plasma of a second processing gas containing a second boron-containing gas and a second nitrogen-containing gas different from the first nitrogen-containing gas.

2. The substrate processing method according to claim 1,
wherein in the forming of the boron nitride film, the boron nitride film is grown in a plane direction of the substrate, starting from the nucleus of the boron nitride-containing material.

3. The substrate processing method according to claim 1,
wherein the first nitrogen-containing gas is at least one of NH₃, a mixed gas of N₂ and H₂, or monomethyl hydrazine.

4. The substrate processing method according to claim 3,
wherein the second nitrogen-containing gas is at least one of N₂ or a mixed gas of N₂ and H₂.

5. The substrate processing method according to claim 4,
wherein the first boron-containing gas and the second boron-containing gas are at least one of B₂H₆, BCl₃, B₃N₃H₆, or B(CH₃)₃.

6. The substrate processing method according to claim 4,
wherein the first boron-containing gas and the second boron-containing gas are different gases.

7. The substrate processing method according to claim 1, further comprising, after the forming of the boron-containing material layer and before the forming of the nucleus of the boron nitride-containing material,
exposing the substrate to a plasma of an inert gas.

8. The substrate processing method according to claim 7,
wherein the first processing gas and the second processing gas contain the inert gas.

9. The substrate processing method according to claim 8, wherein the inert gas is at least one of Ar or He.

10. The substrate processing method according to claim 1,
wherein the foundation layer is any one of SiO₂, HfO₂, SiO₂, HfO₂, HfSiO₄, HfSiON, ZrO₂, amorphous silicon, or sapphire.

11. The substrate processing method according to claim 1,
wherein, in the forming of the boron-containing material layer, the substrate is processed at a temperature within a range of 600° C. to 900° C.

12. The substrate processing method according to claim 1,
wherein, in the forming of the nucleus of the boron-nitride-containing material, the substrate is processed at a temperature within a range of 600° C. to 900° C.

13. The substrate processing method according to claim 1,
wherein, in the forming of the boron nitride film, the substrate is processed at a temperature within a range of 600° C. to 900° C.

14. The substrate processing method according to claim 1,
wherein a pressure in the forming of the nucleus of the boron nitride-containing material is a pressure that is equal to or higher than a pressure in the forming of the boron nitride film.

15. The substrate processing method according to claim 1,
wherein a pressure in the forming of the nucleus of the boron nitride-containing material is within a range of 10 mTorr to 200 mTorr.

16. The substrate processing method according to claim 1,
wherein a pressure in the forming of the boron nitride film is within a range of 10 mTorr to 200 mTorr.

17. The substrate processing method according to claim 1,
wherein a cycle including: the forming of the boron-containing material layer, the forming of the nucleus of the boron nitride-containing material, and the forming of the boron nitride film is repeated a plurality of times.

18. A substrate processing apparatus, comprising:
a processing vessel;
a mounting table that is provided in the processing vessel and configured for a substrate to be mounted thereon;
a gas supply configured to supply a processing gas;
a plasma formation part configured to form a plasma of the processing gas; and
a controller including a processor and a memory,
wherein the controller is configured to perform:
exposing the substrate to a first boron-containing gas;
exposing the substrate to a plasma of a first processing gas containing a first nitrogen-containing gas; and
exposing the substrate to a plasma of a second processing gas containing a second boron-containing gas and a second nitrogen-containing gas different from the first nitrogen-containing gas.

19. The substrate processing apparatus according to claim 18,
wherein the first nitrogen-containing gas is at least one of NH₃, a mixed gas of N₂ and H₂, or monomethyl hydrazine,
the second nitrogen-containing gas is at least one of N₂ or a mixed gas of N₂ and H₂, and
the first boron-containing gas and the second boron-containing gas are at least one of B₂H₆, BCl₃, B₃N₃H₆, or B(CH₃)₃.
